(19) United States
(12) Patent Application Publication
(10) Pub. No.: US 2025/0087612 A1
(43) Pub. Date: Mar. 13, 2025

(54) CONDUCTIVE STRUCTURE, SEMICONDUCTOR CHIP INCLUDING THE SAME AND MANUFACTURING METHOD OF THE CONDUCTIVE STRUCTURE

(71) Applicant: Samsung Electronics Co., Ltd., Suwon-si (KR)

(72) Inventors: JUNHYUN AN, Suwon-si (KR); UN-BYOUNG KANG, Suwon-si (KR); HYOJIN YUN, Suwon-si (KR); SEUNG HUN CHAE, Suwon-si (KR); JU-IL CHOI, Suwon-si (KR)

(21) Appl. No.: 18/626,272

(22) Filed: Apr. 3, 2024

(30) Foreign Application Priority Data
Sep. 7, 2023 (KR) 10-2023-0118841

(51) Int. Cl. H01L 23/00

(52) U.S. Cl. CPC H01L 24/13; H01L 24/03; H01L 24/04; H01L 24/05; H01L 24/11; H01L 2224/0345; H01L 2224/03452; H01L 2224/03912; H01L 2224/0401; H01L 2224/05022; H01L 2224/05124; H01L 2224/05147; H01L 2224/05555; H01L 2224/05558; H01L 2224/05562; H01L 2224/05611; H01L 2224/05616; H01L 2224/05624; H01L 2224/05639; H01L 2224/05644; H01L 2224/05647; H01L 2224/05664; H01L 2224/05666; H01L 2224/05669; H01L 2224/05671; H01L 2224/1145; H01L 2224/11452; H01L 2224/11462; H01L 2224/1161; H01L 2224/119; H01L 2224/13007; H01L 2224/13014; H01L 2224/13084; H01L 2224/13111; H01L 2224/13116; H01L 2224/13124; H01L 2224/13139; H01L 2224/13144; H01L 2224/13147; H01L 2224/13155; H01L 2224/13164; H01L 2224/13166; H01L 2224/13169; H01L 2224/13171

(57) ABSTRACT

The present disclosure relates to a conductive structure including: a conductive pad that includes a first seed layer having a first area and a second area surrounding the first area, and a first metal layer disposed on the first area of the first seed layer; and a conductive pillar disposed on the conductive pad, wherein a thickness of the conductive pad in an area vertically overlapping the first area of the first seed layer is thicker than a thickness of the conductive pad in an area vertically overlapping the second area of the first seed layer, a semiconductor chip including the conductive structure, and a manufacturing method of the conductive structure.

### CROSS-REFERENCE TO RELATED APPLICATION

This application claims priority under 35 U.S.C § 119 to and the benefit of Korean Patent Application No. 10-2023-0118841 filed in the Korean Intellectual Property Office on Sep. 7, 2023, the entire contents of which are incorporated herein by reference.

### BACKGROUND OF THE INVENTION

### (a) Field of the Invention

The present disclosure relates to a conductive structure, a semiconductor chip including the conductive structure, and a manufacturing method of the conductive structure.

### (b) Description of the Related Art

In the semiconductor package field, flip chip technology, which connects a semiconductor chip and a substrate with a bump when mounting the semiconductor chip on the substrate, is widely used. Such flip chip technology is gradually evolving from a technology of forming a solder bump on the semiconductor chip to a pillar bump technology of forming a conductive pillar such as a copper pillar and a solder cap in order to reduce sizes and pitch of bumps.

In the pillar bump technology, a conductive pillar may be formed by electroplating, which forms a seed layer on a bump pad and applies a current to the seed layer to grow a metal on the seed layer. In this case, for efficient metal growth, it is essential that sufficient current is applied to the seed layer.

### SUMMARY OF THE INVENTION

In one aspect, the present disclosure reduces/blocks possibilities of defects in which conductive pillars are not formed by preventing undercuts that may occur during an etching process.

As an embodiment of the present disclosure, a conductive structure including: a conductive pad that includes a first seed layer having a first area and a second area surrounding the first area, and a first metal layer disposed on the first area of the first seed layer; and a conductive pillar disposed on the conductive pad, wherein a thickness of the conductive pad in an area vertically overlapping the first area of the first seed layer is thicker than a thickness of the conductive pad in an area vertically overlapping the second area of the first seed layer is provided.

As another embodiment of the present disclosure, a semiconductor chip including: a body comprising a connection pad; and a conductive structure disposed on the connection pad, wherein the conductive structure includes: a conductive pad that includes a first seed layer including a first area and a second area surrounding the first area, and a first metal layer disposed on the first area of the first seed layer; and a conductive pillar disposed on the conductive pad, and a thickness of the conductive pad in an area vertically overlapping the first area of the first seed layer is thicker than a thickness of the conductive pad the first seed layer in an area vertically overlapping the second area of the first seed layer is provided.

As another embodiment of the present disclosure, a manufacturing method of a conductive structure is provided. The manufacturing method of a conductive structure includes: forming a conductive pad; and forming a conductive pillar on the conductive pad, wherein the forming of the conductive pad includes: forming a first seed layer including a first area and a second area surrounding the first area; forming a first metal layer on the first area of the first seed layer; forming a photoresist layer to cover the second area of the first seed layer and the first metal layer; etching an exposed area of the first seed layer; and removing the photoresist layer.

According to one aspect of the present disclosure, the possibilities of defects in which a conductive pillar is not formed can be prevented by preventing undercuts that may occur during an etching process.

### BRIEF DESCRIPTION OF THE DRAWINGS

FIG. 1 is a cross-sectional view of a conductive structure according to an embodiment of the present disclosure.

FIG. 2 is a top plan view of the conductive structure according to an embodiment of the present disclosure.

FIG. 3 is a cross-sectional view of a semiconductor chip including the conductive structure according to an embodiment of the present disclosure.

FIG. 4 to FIG. 7 show a case where an undercut occurs during an etching of the seed layer and a conductive pillar is not formed.

FIG. 8 to FIG. 17 are manufacturing process diagrams of a conductive structure according to embodiments of the present disclosure.

### DETAILED DESCRIPTION OF THE EMBODIMENTS

Hereinafter, with reference to the accompanying drawing, several exemplary embodiments of present disclosure will be explained in detail such that a person of an ordinary skill in the technical field to which the present disclosure belongs can easily practice it. As those skilled in the art would realize, the described embodiments may be modified in various different ways, all without departing from the spirit or scope of the present disclosure.

In order to clearly describe the disclosure with reference to the drawings, parts not closely related to the description of key features are omitted, and similar reference numerals are designated to similar parts throughout the specification.

In addition, size and thickness of each component shown in the drawing are arbitrarily indicated for convenience of description and thus the present disclosure is not necessarily limited to what is shown. In the drawings, thicknesses of layers, films, panels, areas, etc., are exaggerated for clarity. In addition, in the drawings, for convenience of description, the thicknesses of some layers and areas are exaggerated.

Throughout this specification and the claims that follow, when it is described that an element is “coupled” to another element, it includes not only “directly connected”, but also “indirectly connected” between other members. In a similar sense, this includes being “physically connected” as well as being “electrically connected”. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, area, or substrate is referred to as being “on” another element, it can be directly on the other element or intervening elements may also be present. In contrast, when an element is referred to as being “directly on” another element, there are no intervening elements present. Further, when an element is “on” or “above” a reference portion, the element is located above or below the reference portion, and it does not necessarily mean that the element is located “on” or “above” in a direction opposite to gravity.

Further, throughout the specification, when it is referred to as a “plan view”, it means the case where a target part is viewed from above, and when it is referred to as “in a cross-section”, it means the case where a cross-section obtained by vertically cutting the target part is viewed from a side.

In the present specification, the terms including ordinal numbers such as first, second, and the like may be used to describe various elements, but the elements are not limited by the terms. Accordingly, a component referred to as a first constituent element in one part of this specification may be referred to as a second constituent element in another part of this specification.

In addition, throughout the specification, references to any constituent elements in singular may include/indicate references to a plurality of those constituent elements, unless specifically stated to the contrary. For example, “a metal layer” may be used to mean not only one metal layer, but also one or another of a plurality of metal layers, such as two, three or more.

Hereinafter, a conductive structure, a semiconductor chip including the conductive structure, and a manufacturing method of the conductive structure according to the present disclosure will be described with reference to the accompanying drawings.

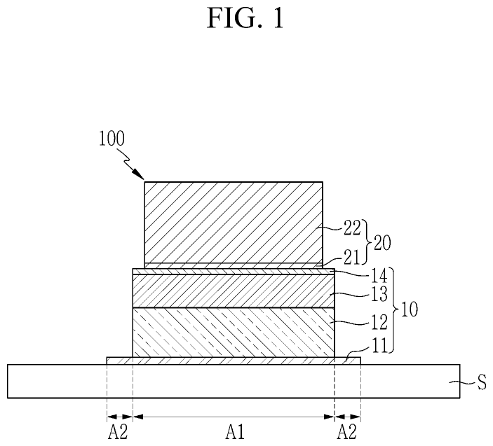

FIG. 1 is a cross-sectional view of a conductive structure according to an embodiment of the present disclosure.

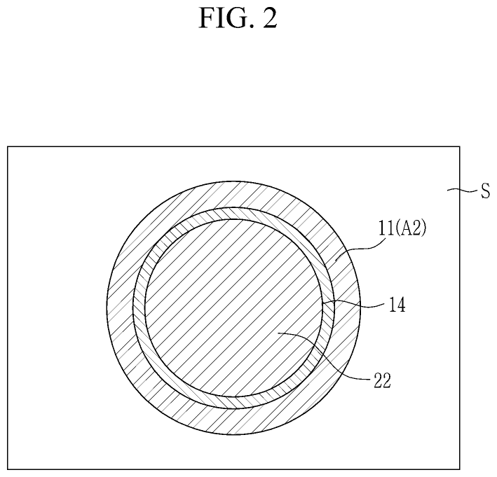

FIG. 2 is a top plan view of the conductive structure according to an embodiment of the present disclosure.

Referring to FIG. 1 and FIG. 2, conductive structure 100 according to embodiments of the present disclosure may include a conductive pad 10 and a conductive pillar 20 disposed on the conductive pad 10.

The conductive pad 10 may include a first seed layer 11 including a first area A1 and a second area A2 surrounding the first area A1, and a first metal layer 12 disposed on the first area A1 of the first seed layer 11.

The conductive pad 10 may further include at least one of metal layers 13 and 14 disposed on the first metal layer 12. For example, as shown in the drawing, the conductive pad 10 may further include a second metal layer 13 disposed on the first metal layer 12 and a third meal layer 14 disposed on the second metal layer 13.

The conductive pad 10 may have a circular cylinder shape (e.g., a cylindrical shape). For example, each of the first seed layer 11, the first metal layer 12, the second metal layer 13, and the third metal layer 14 may have a circular cylinder shape (e.g., a cylindrical shape). In this case, a diameter of the first seed layer 11 may be larger than a diameter of the first metal layer 12 by the second area A2 of the first seed layer 11, e.g., in that the second area A2 of the first seed layer 11 does not vertically overlap the first metal layer 12. The diameter of the first seed layer 11 may be larger than a diameter of each of the second metal layer 13 and the third metal layer 14 disposed on the first metal layer 12.

The first area A1 and the second area A2 of the first seed layer 11 are to distinguish between an area where the first metal layer 12 is disposed and an area where the first metal layer 12 is not disposed, and the first area A1 and the second area A2 of the first seed layer 11 are integrally formed and there is no visible/detectable boundary formed between them, e.g., within the first seed layer 11. The first area A1 and the second area A2 of the first seed layer 11 have the same thickness, and thus there is no step between the first area A1 and the second area A1 and may be flat throughout the first area A1 and the second area A2 of the first seed layer 11.

The first seed layer 11 may be a metal thin film for forming the first metal layer 12.

The first seed layer 11 may be formed using a physical vapor deposition method (PVD), but this is not restrictive, and may be formed using a chemical vapor deposition (CVD) method, an atomic layer deposition (ALD) method, a vacuum deposition method, and the like.

Conductive materials may be used as a material for the first seed layer 11, and, for example, copper (Cu), gold (Au), aluminum (Al), silver (Ag), platinum (Pt), tin (Sn), chromium (Cr), palladium (Pd), lead (Pb), titanium (Ti), or their alloys may be used. For example, the first seed layer 11 may be formed of one or more materials mentioned above.

The first metal layer 12 may provide excellent electrical connection and reliability between the conductive pad 10 and components connected thereto.

The first metal layer 12 may be disposed only on the first area A1 of the first seed layer 11, and may not be disposed on the second area A2. Therefore, the first area A1 of the first seed layer 11 may overlap the first metal layer 12 in a plan view, and the boundary between the first area A1 and the second area A2 may overlap an exterior circumference of the first metal layer 12. For example, the first area A1 of the first seed layer 11 is an area vertically overlapping the first metal layer 12, and the second area A2 of the first seed layer 11 is an area vertically non-overlapping the first metal layer 12. For example, the boundary between the first area A1 and the second area A2 of the first seed layer 11 may vertically overlap a side surface of the first metal layer 12. A thickness of the conductive pad 10 in an area including the first area A1 of the first seed layer 11 may be thicker than a thickness of the conductive pad 10 in an area including the second area A2 of the first seed layer 11. For example, the thickness of the conductive pad 10 vertically overlapping the second area A2 of the first seed layer 11 may be the same as a thickness of the first seed layer 11 in the second area A2, and the thickness of the conductive pad 10 vertically overlapping the first area A1 of the first seed layer 11 may be a sum of a thickness of the first seed layer 11 in the first area A1, a thickness of the first metal layer 12, a thickness of the second metal layer 13, and a thickness of the third metal layer 14. Therefore, the conductive pad 10 may be thicker in an area vertically overlapping the first area A1 of the first seed layer 11 than in an area vertically overlapping the second area A2 of the first seed layer 11. The thickness of the first seed layer 11 in the first area A1 may be the same as the thickness of the first seed layer 11 in the second area A2.

The first metal layer 12 may be formed by, for example, electroplating, but is not limited thereto.

Conductive materials may also be used as a material for the first metal layer 12, and, for example, copper (Cu), gold (Au), aluminum (Al), silver (Ag), platinum (Pt), tin (Sn), chromium (Cr), palladium (Pd), lead (Pb), titanium (Ti), or their alloys may be used. For example, the first metal layer 12 may be formed of one or more materials mentioned above. The material of first metal layer 12 may be the same as the material of first seed layer 11, or may be different.

The thickness of the first metal layer 12 may be thicker than the thickness of the first seed layer 11, which is a metal thin film.

The second metal layer 13 may function as a diffusion barrier that suppresses compound growth between metals due to reactions between metals, alleviates stress due to differences in coefficient of thermal expansion (CTE) between metal layers, and improves adherence between the metal layers.

In the foregoing aspect (e.g., as a barrier layer), the second metal layer 13 may include or be formed of nickel (Ni).

The second metal layer 13 may be formed by using the same photoresist film as the first metal layer 12. For example, the first metal layer 12 and the second metal layer 13 may be sequentially formed by using the same photoresist pattern, and thus the diameter of the second metal layer 13 may be substantially the same as the diameter of the first metal layer 12. However, this is not restrictive, and for example, the diameter of the second metal layer 13 may be smaller than the diameter of the first metal layer 12. In the present disclosure, the expression, “substantially identical (or substantially the same)” means not only being physically the same, but also including an error range depending on the manufacturing process or measurement method, e.g., acceptable variations that may occur due to manufacturing processes. For example, the expression “substantially the same” may include values/dimensions of 99%, 99.9%, 99.7%, 99.5%, 99%, 98.5% or 98% of the target values/dimensions.

The thickness of the second metal layer 13 may be thinner than the thickness of the first metal layer 12. The electrical conductivity of the second metal layer 13 may be lower than that of the first metal layer 12, which provides an excellent electrical connection, and in this case, it may be desirable for the thickness of the second metal layer 13 to be thinner than the thickness of the first metal layer 12. However, this is not restrictive, and depending on materials of the second metal layer 13, the thickness of the second metal layer 13 may be thicker than the thickness of the first metal layer 12 or may be substantially the same as the thickness of the first metal layer 12.

The third metal layer 14 may prevent corrosion and oxidation of a metal covered by the third metal layer 14. For example, the third metal layer 14 may protect the second metal layer 13 from corrosion and oxidation, and may provide excellent electrical connection between the conductive pad 10 and the conductive pillar 20, resulting in stable signal transmission.

In the above-described aspect, the third metal layer 14 may include or be formed of gold (Au).

The third metal layer 14 may also be formed by using the same photoresist layer as the first metal layer 12. For example, the first metal layer 12, the second metal layer 13, and the third metal layer 14 may be sequentially formed by using the same photoresist pattern, and a diameter of the third metal layer 14 may be substantially the same as the diameter of the first metal layer 12. However, methods/structures are not limited to the ones mentioned above, and for example, the diameter of the third metal layer 14 may be smaller than the diameter of the first metal layer 12. The diameter of the third metal layer 14 may be substantially the same as the diameter of the second metal layer 13, or may be smaller than the diameter of the second metal layer 13.

The thickness of the third metal layer 14 may be thinner than the thickness of the first metal layer 12. The electrical conductivity of the third metal layer 14 may also be lower than that of the first metal layer 12, which provides excellent electrical connection, and in this case, it may be desirable for the thickness of the third metal layer 14 to be thinner than the thickness of the first metal layer 12. In order to reduce manufacturing costs and the like, it may be desirable for the third metal layer 14 to be a metal thin film, and the thickness of the third metal layer 14 may be thinner than the thickness of the second metal layer 13.

The conductive pillar 20 is disposed on the conductive pad 10 and may include a second seed layer 21 and a fourth metal layer 22 disposed on the second seed layer 21.

The conductive pillar 20 may also have a circular cylinder shape (e.g., a cylindrical shape) like the conductive pad 10, and each of the second seed layer 21 and the fourth metal layer 22, which are components of conductive pillar 20, may also have a circular cylinder shape (e.g., a cylindrical shape).

The second seed layer 21 may be a metal thin film to form the second metal layer 13.

The second seed layer 21 may be formed using a physical vapor deposition method (PVD), but this is not restrictive, and may be formed using a chemical vapor deposition (CVD) method, an atomic layer deposition (ALD) method, a vacuum deposition method, and the like.

Conductive materials may be used as a material for the second seed layer 21, and, for example, copper (Cu), gold (Au), aluminum (Al), silver (Ag), platinum (Pt), tin (Sn), chromium (Cr), palladium (Pd), lead (Pb), titanium (Ti), or their alloys may be used. For example, the second seed layer 21 may be formed of one or more materials mentioned above.

The fourth metal layer 22 may provide excellent electrical connection and reliability between the conductive pad 10 and components electrically connected thereto. As used herein, components described as being “electrically connected” are configured such that an electrical signal can be transferred from one component to the other (although such electrical signal may be attenuated in strength as it transferred and may be selectively transferred).

The fourth metal layer 22 may be formed by, for example, electroplating, but is not limited thereto.

Conductive materials may also be used as a material for the fourth metal layer 22, and, for example, copper (Cu), gold (Au), aluminum (Al), silver (Ag), platinum (Pt), tin (Sn), chromium (Cr), palladium (Pd), lead (Pb), titanium (Ti), or their alloys may be used. For example, the fourth metal layer 22 may be formed of one or more materials mentioned above. The material of fourth metal layer 22 may be the same as the material of first seed layer 11, or may be different.

A thickness of the fourth metal layer 22 may be thicker than a thickness of the second seed layer 21 which is a metal thin film. The thickness of the fourth metal layer 22 may be thicker than each of the thicknesses of the first seed layer 11, first to third metal layers 12, 13, and 14. The conductive pillar 20 may have a pillar shape due to the thick fourth metal layer 22. For example, the conductive pillar 20 may have a shape of an upright post.

As described later, a photoresist layer used for forming the fourth metal layer 22 may cover a portion of the second seed layer 21 placed on the conductive pad 10, and therefore the diameter of the fourth metal layer 22 may be smaller than the diameter of the conductive pad 10. For example, the diameter of the fourth metal layer 22 may be smaller than each of the diameters of the first seed layer 11 and the first to third metal layers 12, 13, and 14. Such a structure may reduce/prevent defects of the fourth metal layer 22 caused by covering side surfaces of the conductive pad 10.

Undercuts may occur in a process of etching/removing unnecessary areas of the second seed layer 21, and in this case, the diameter of the second seed layer 21 may be smaller than the diameter of the fourth metal layer 22. However, the diameter of the second seed layer 21 may be substantially the same as the diameter of the fourth metal layer 22, and when the photoresist layer used in etching the second seed layer 21 covers a part of the second seed layer 21, the diameter of the second seed layer 21 may be larger than the diameter of the fourth metal layer 22.

From a similar perspective to the ones described above, the diameter of the conductive pillar 20 may be smaller than the diameter of the conductive pad 10. The diameter of the fourth metal layer 22 may be smaller than the diameter of each of the first seed layer 11 and the first to third metal layers 12, 13, and 14 that form the conductive pad 10, and the diameter of the second seed layer 21 may be smaller than or substantially equal to the diameter of the fourth metal layer 22.

The conductive structure 100 may be disposed on a substrate S.

The substrate S may be a connection pad 220 of the semiconductor chip 200, which will be described later. The conductive pad 10 may function as and/or may be a bump pad, and a component such as a tin-silver (Sn—Ag) solder cap may be additionally placed on the conductive pillar 20. However, the substrate S on which the conductive structure 100 is placed is not limited to the connection pad 220 of the semiconductor chip 200.

In certain embodiments, the conductive pad 10 according to the present disclosure is composed of the seed layer 11 including the first area A1 and the second area A2, and the metal layer 12, independently from the conductive pillar 20, and may be applied to wiring patterns, conductive posts, and the like. In this case, problems such as reliability deteriorated due to undercut of the seed layer can be prevented. For example, the conductive pad 10 may be integrally formed with other wiring patterns (e.g., including circuits and/or conductive posts), thereby preventing disconnections between the conductive pad 10 and the other wiring patterns in certain embodiments.

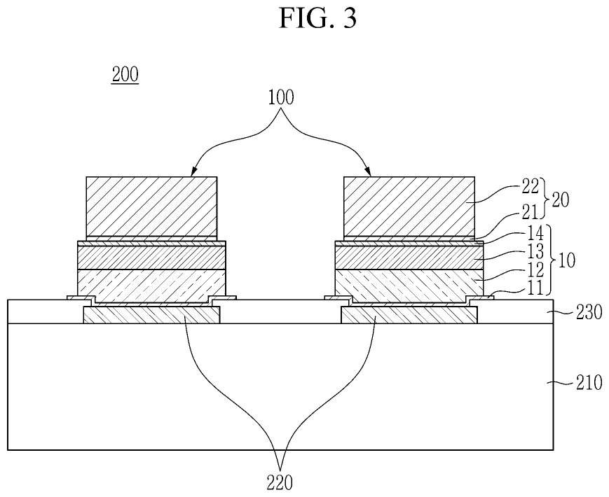

FIG. 3 is a cross-sectional view of a semiconductor chip including the conductive structure according to an embodiment of the present disclosure.

Referring to FIG. 3, the semiconductor chip 200 may include a body 210 including the connection pad 220 and the conductive structure 100 disposed on the connection pad 220. The semiconductor chip 200 may further include a protective layer 230 that is disposed on the body 210 and exposes the connection pad 220.

The body 210 may include a semiconductor wafer, a plurality of various types of individual devices, and an interlayer insulation layer.

The semiconductor wafer may contain or be formed of one or more of compounds such as silicon (Si), germanium (Ge), gallium arsenide (GaAs), and silicon carbide (SiC).

The plurality of individual devices may include a metal-oxide-semiconductor field effect transistor (MOSFET), a system large scale integration (LSI), an image sensor such as a CMOS imaging sensor (CIS), active devices, passive devices, and the like.

The interlayer insulation layer may include or be formed of a silicon oxide, a silicon nitride, and the like.

The connection pad 220 may electrically connect the semiconductor chip 200 to external components. The connection pad 220 may protrude on a surface (e.g., on a top surface) of the body 210, and/or at least a partial area of the connection pad 220 may be buried in other parts of the body 210 and exposed on one surface (e.g., on the top surface) of the body 210. For example, other parts (e.g., an insulation layer) of the body 210 may cover and contact a side surface and/or a top surface of the connection pad 220. Conductive materials such as aluminum (Al) and copper (Cu) may be used as materials for the connection pad 220. For example, the connection pad 220 may be formed of conductive material, e.g., aluminum and/or copper.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact.

The protective layer 230 may protect a surface (e.g., the top surface) of the body 210 physically, mechanically, and chemically. The protective layer 230 may cover a portion of the connection pad 220, for example, an exterior circumference area of the connection pad 220. For example, the protective layer 230 may contact a top surface of the connection pad 220. As shown in FIG. 3, the protective layer 230 may be thinner in a part vertically overlapping the connection pad 220 than another part which does not vertically overlap the connection pad 220. Although not specifically shown in the drawing, the protective layer 230 may have a step difference between an area covering the body 210 and an area covering the connection pad 220 because of a thickness of the protective layer 230 and/or because of a thickness of the connection pad 220. For example, a first upper surface of the protective layer 230 vertically overlapping the connection pad 220 may be at a higher level than a second upper surface of the protective layer 230 which does not vertically overlap the connection pad 220. For example, an upper surface of the protective layer 230 may have a step structure in some embodiments, and a lower surface of the protective layer 230 may have a step structure in some other embodiments. In certain embodiments, both of the upper surface and the lower surface of the protective layer 230 may have step structures. The protective layer 230 may be a silicon oxide layer, a silicon nitride layer, or a polymer layer. The protective layer 230 may be formed of a plurality of layers each composed of one or more materials among these (silicon oxide, silicon nitride, and polymers).

When the semiconductor chip 200 includes the protective layer 230, the first seed layer 11 extends over the protective layer 230 and may be placed on the protective layer 230 (e.g., on a top surface of the protective layer 230). In this case, the first seed layer 11 may further cover/contact a side surface of the protective layer 230. The first metal layer 12 may also be placed on the first seed layer 11 placed on the protective layer 230. For example, the first metal layer 12 may vertically overlap a portion of the protective layer 230 as shown in FIG. 3. In this case, in the first metal layer 12, a first area placed on the connection pad 220 and a second area placed on the protective layer 230 may have a step due to a difference in the thickness between the first area and the second area of the first metal layer 12. For example, the first area of the first metal layer 12 may not vertically overlap the protective layer 230, and the second area of the first metal layer 12 may vertically overlap the protective layer 230.

By providing the semiconductor chip 200 containing/including the conductive pad 10 and the conductive pillar 20, the semiconductor chip 200 may be electrically connected to other configurations/devices with bumps of small size and short pitch.

As will be described later, problems of the fourth metal layer 22 not being formed or not growing sufficiently can be prevented through the structure in which the second area A2 of the first seed layer 11 remains. For example, the second area A2 of the first seed layer 11 may be helpful for forming the fourth metal layer 22.

Since the description of each configuration of conductive structure 100 is the same as described above, detailed description thereof will be omitted.

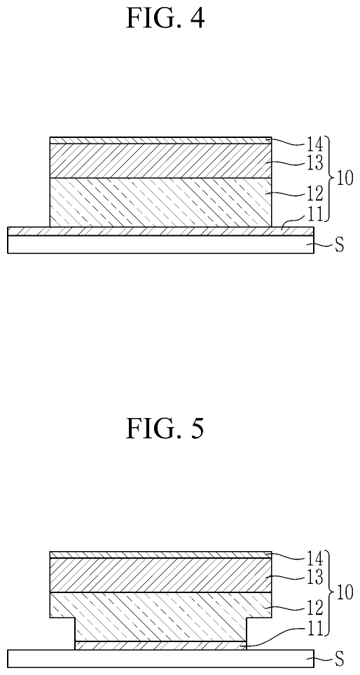

FIG. 4 to FIG. 7 show a case where an undercut occurs during etching of the seed layer and a conductive pillar is not formed.

First, referring to FIG. 4, the first seed layer 11, the first metal layer 12, the second metal layer 13, and the third metal layer 14 are formed on the substrate S. The first seed layer 11 may be formed by physical vapor deposition method (PVD), and the first to third metal layers 12, 13, and 14 each may be formed by electroplating.

Next, referring to FIG. 5, an unnecessary area of the first seed layer 11 is etched/removed. In this case, undercut where a part of the first seed layer 11 and the first metal layer 12 is etched excessively compared to the design may occur. For example, the first seed layer 11 and the first metal layer 12 may be over etched, thereby forming an undercut in the first seed layer 11 and the first metal layer 12 as shown in FIG. 5.

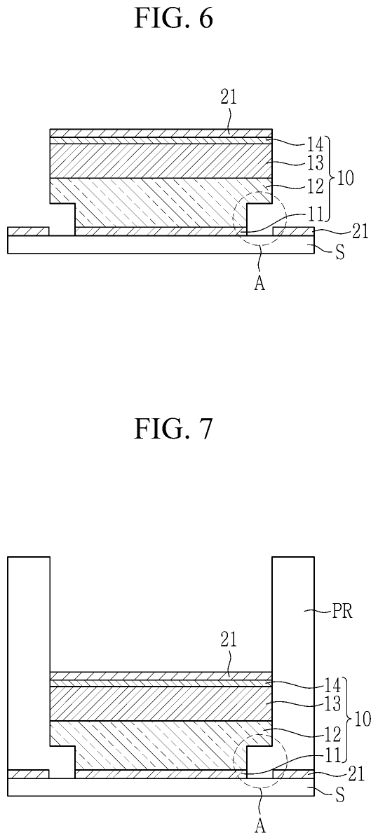

Next, referring to FIG. 6, the second seed layer 21 is formed on the substrate S and the third metal layer 14. In this case, it may be difficult for the second seed layer 21 to be formed in an area A where the undercut occurred. For example, when the second seed layer is formed by physical vapor deposition method (PVD), an upper portion of the area A where the undercut occurred is covered with the first metal layer 12, the second metal layer 13, and the third metal layer 14 such that the second seed layer 21 may be difficult to be formed in the area A. Accordingly, the second seed layer 21 formed on the substrate S is disconnected from the first seed layer 11 and the first metal layer 12, and thus may also be disconnected from the second seed layer 21 disposed on the conductive pad 10 and the third metal layer 14. For example, because of the disconnection/undercut, an electrical signal may not be transferred from the second seed layer 21 formed on the substrate S to the second seed layer 21 formed on the conductive pad 10 (e.g., on the third metal layer 14).

Next, referring to FIG. 7, a photoresist layer PR is formed on the second seed layer 21, and electroplating is carried out to form the fourth metal layer 22. In this case, in the area A where the undercut occurred, the second seed layer 21 formed on the substrate S is disconnected from the first seed layer 11 and the first metal layer 12 such that a current is applied only to the second seed layer 21 formed on substrate S and may not be applied to configurations (the conductive pad 10 and the second seed layer 21 formed on the conductive pad 10) that are disconnected from the second seed layer 21. Therefore, a problem may occur in which the fourth metal layer 22 is not formed on the second seed layer 21, or even if a portion is formed, the metal forming the fourth metal layer 22 does not grow sufficiently.

According to a manufacturing process of the conductive structure according to the present disclosure such a problem can be prevented, and this will be described hereinafter.

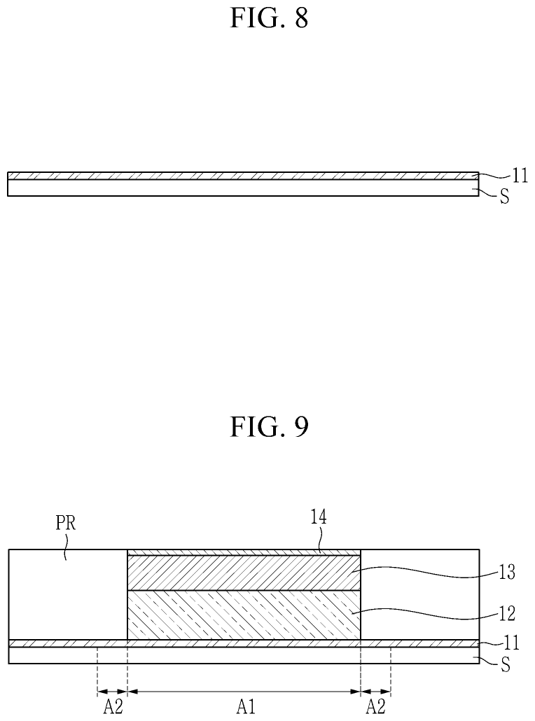

FIG. 8 to FIG. 17 are manufacturing process diagrams of a conductive structure according to embodiments of the present disclosure.

A manufacturing method of a conductive structure 100 according to an embodiment of the present disclosure includes forming a conductive pad 10 and forming a conductive pillar 20 on the conductive pad 10.

The forming of the conductive pad 10 may include forming a first seed layer 11 including a first area A1 and a second area A2 surrounding the first area A1, forming a first metal layer 12 on the first area A1 of the first seed layer 11, forming a photoresist layer PR to cover the second area A2 of the first seed layer 11, adjacent to the first area A1, and the first metal layer 12, etching an exposed area of the first seed layer 11, and removing the photoresist layer PR.

The forming of the conductive pad 10 may further include forming a second metal layer 13 on the first metal layer 12. The forming of the conductive pad 10 may further include forming a third metal layer 14 on the second metal layer 13. In this case, in the forming of the photoresist layer PR, the photoresist layer PR may be formed to further cover the second metal layer 13 and the third metal layer 14.

The forming of the conductive pillar 20 may include forming a second seed layer 21 and forming a fourth metal layer 22 on the second seed layer 21.

In the forming of the second seed layer 21, second seed layer 21 may be formed on the first metal layer 12 and on the second area A2 of the first seed layer 11. In this case, the forming of the conductive pillar 20 may further include etching the second seed layer 21 formed on the second area A2 of the first seed layer 11.

Hereinafter, referring to the accompanying drawings, each step of the manufacturing method of the conductive structure 100 according to some embodiments of the present disclosure will be described.

Referring to FIG. 8, the first seed layer 11 may be formed on the substrate S. The first seed layer 11 may be formed using a physical vapor deposition method (PVD), but this is not restrictive, and may be formed using a chemical vapor deposition (CVD) method, an atomic layer deposition (ALD) method, a vacuum deposition method, and the like.

Next, referring to FIG. 9, the photoresist PR is formed on the first seed layer 11, and the first metal layer 12, the second metal layer 13, and the third metal layer 14 may be formed.

The photoresist layer PR may be formed on the second area A2 of the first seed layer 11, which is an area where the first metal layer 12, the second metal layer 13, and the third metal layer 14 are not formed.

The photoresist layer PR may be a photoresist layer commonly used in the semiconductor industry. The photoresist layer PR may be formed by, for example, applying a photoresist liquid on the substrate S and forming a pattern by exposing and developing. The photoresist layer PR may be either a positive type in which the exposed area is removed or a negative type in which the exposed area remains after development.

The first metal layer 12, the second metal layer 13, and the third metal layer 14 may be formed on the first area A1 of the first seed layer 11, which is an area in which the photoresist layer PR is not formed (e.g., is removed).

The first metal layer 12, the second metal layer 13, and the third metal layer 14 may be sequentially formed. For example, the first metal layer 12 may be formed on the first area A1 of the first seed layer 11, the second metal layer 13 may be formed on the first metal layer 12, and then the third metal layer 14 may be formed on the second metal layer 13. Each of the first metal layer 12, the second metal layer 13, and the third metal layer 14 may be formed by electroplating. When plating the first metal layer 12, the second metal layer 13, and the third metal layer 14, the same photoresist layer may be used, and therefore the diameters of the first metal layer 12, the second metal layer 13, and the third metal layer 14 may be substantially the same.

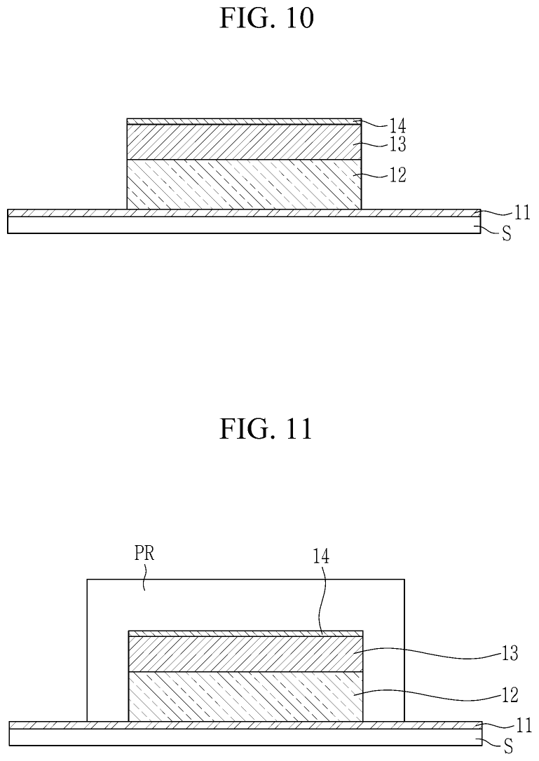

Next, referring to FIG. 10, the photoresist layer PR is removed. The photoresist layer may be removed by stripping, and the second area A2 of the first seed layer 11 may be exposed by removing the photoresist layer PR.

Next, referring to FIG. 11, the photoresist layer PR may be formed to cover the second area A2 of the first seed layer 11 and the first metal layer 12. The photoresist layer PR covering the first metal layer 12 is not necessarily in contact with and covers a top surface of the first metal layer 12, and may be disposed on the first metal layer 12 to cover the first metal layer without contacting the top surface of the first metal layer 12. For example, when the conductive pad 10 further includes the second metal layer 13 and the third metal layer 14, the photoresist layer PR is disposed on the second metal layer 13 and the third metal layer 14 and may further cover the second metal layer 13 and the third metal layer 14. As shown in the drawing, the photoresist layer PR may cover the second area A2 of the first seed layer, adjacent to the first area A1, the side surfaces of the first to third metal layers 12, 13, and 14, and the top surface of the third metal layer 13 disposed at the top.

The description of the formation method and type of the photoresist layer PR is the same as corresponding descriptions above, and thus detailed description is omitted.

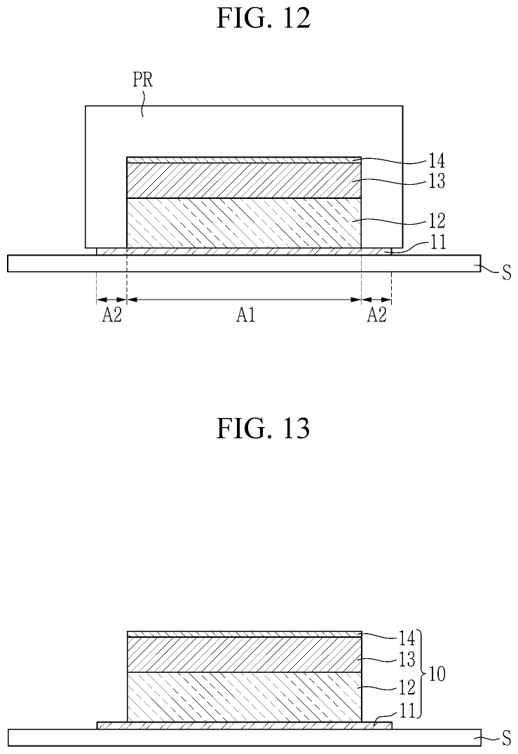

Next, referring to FIG. 12, an exposed area of the first seed layer 11 may be etched. The exposed area of the first seed layer 11 means an area not covered by the photoresist layer (PR). For example, the exposed area of the first seed layer 11 may be an area excluding/outside the second area A2 of first seed layer 11, adjacent to the first area A1. As shown in the drawing, an undercut may occur and thus a part (a part of the area covered by the photoresist layer) of the first seed layer 11, adjacent to the second area A2 is etched together during the etching, but this is not restrictive. As the first seed layer 11 is etched, a part of the substrate S may be exposed.

Next, referring to FIG. 13, the photoresist layer PR is removed. The photoresist layer may be removed by stripping, and the second area A2 of the first seed layer 11, remaining after the etching may be exposed by removing the photoresist layer PR.

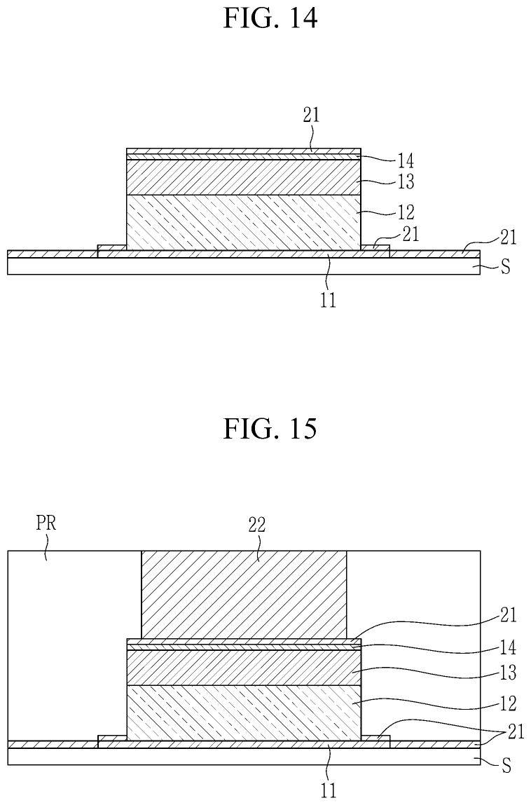

Next, referring to FIG. 14, the second seed layer 21 may be formed. The second seed layer 21 may be formed on the first metal layer 12 and on the second area A2 of the first seed layer 11, remaining after the etching. When the conductive pad 10 further includes the second metal layer 13 and the third metal layer 14, the second seed layer 21 is formed on the second metal layer 13 and the third metal layer 14 to cover/contact the third metal layer 14. As the first seed layer 11 has been etched and removed from the substrate S to expose portions of the substrate S, the second seed layer 21 may be further formed on the exposed substrate S.

The second seed layer 21 may be formed using a physical vapor deposition method (PVD), but this is not restrictive, and may be formed using a chemical vapor deposition (CVD) method, an atomic layer deposition (ALD) method, a vacuum deposition method, and the like.

Next, referring to FIG. 15, the photoresist layer PR is formed in an area excluding an area where the fourth metal layer 22 is to be formed, and then the fourth metal layer 22 may be formed. The photoresist layer PR may be formed on the second seed layer 21 formed on the second area A2 of the first seed layer 11 and the second seed layer 21 formed on the substrate S.

As shown in the drawing, the photoresist layer PR may cover a portion of the second seed layer 21 disposed on the conductive pad 10, and through this, defects that may occur when a plating material covers the side surface of the conductive pad 10 when forming the fourth metal layer 22 can be prevented from occurring. Accordingly, the fourth metal layer 22 may be formed to have a smaller diameter than each of the first seed layer 11 and the first to third metal layers 12, 13, and 14.

The description of the formation method and type of the photoresist layer (PR) is the same as corresponding descriptions above, and therefore detailed description is omitted.

The fourth metal layer 22 may be formed on the second seed layer 21 formed on an area where the photoresist layer PR is not formed, e.g., on the first to third metal layers 12, 13, and 14. The fourth metal layer 22 may be formed by electroplating. When forming the fourth metal layer 22, a current may be applied to the second seed layer 21 disposed on the conductive pad 10 via the second seed layer 21 formed on the substrate S and the conductive pad 10 including the first seed layer 11 and the first metal layer 12. During electroplating, the plating speed and plating thickness may be adjusted by controlling the current density and plating time, and the fourth metal layer 22 with a thick thickness may be formed.

When the photoresist layer PR covers a portion of the second seed layer 21 placed on the conductive pad 10, the fourth metal layer 22 may be formed to have a smaller diameter than the conductive pad 10.

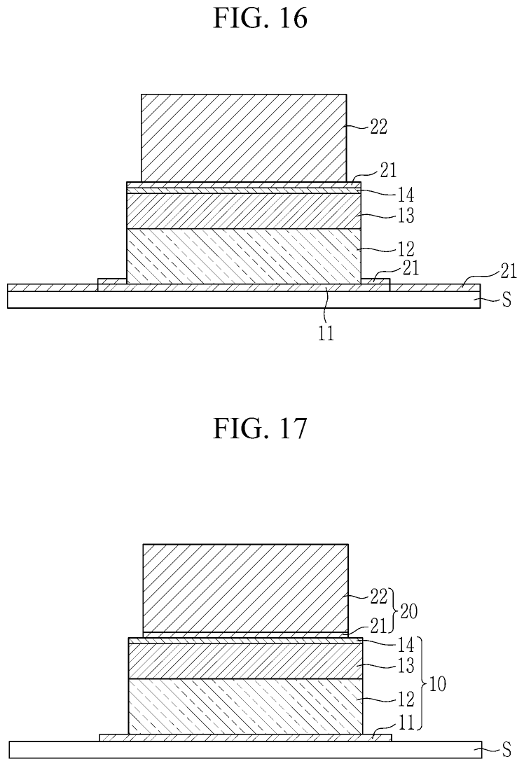

Next, referring to FIG. 16, the photoresist layer PR is removed. The photoresist layer may be removed by stripping, and second seed layer 21 may be exposed as the photoresist layer PR is removed.

Next, referring to FIG. 17, the exposed area of the second seed layer 21 may be etched. Before etching, the second seed layer 21 is disposed on the second area A2 of the first seed layer 11, and only the second seed layer 21 is disposed on the substrate S, and thus when the second seed layer 21 is etched at a constant etching rate, the second area A2 of first seed layer 11 may remain without being etched. Therefore, the conductive structure 100 may include the second area A2 of the first seed layer 11 that remains without being etched.

According to the manufacturing method of the conductive structure 100 according to the present disclosure, the second area A2 of first seed layer 11 adjacent to the first area A1 is protected with the photoresist layer PR, thereby preventing an undercut caused by excessive etching of the first seed layer 11 and the first metal layer 12. Therefore, a sufficient current may be applied to the second seed layer 21 disposed on the conductive pad 10 via the conductive pad 10, which includes the first seed layer 11 and the first metal layer 12, and problems in which the fourth metal layer 22 is not formed or the fourth metal layer 22 is not sufficiently grown can be prevented.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

While this invention has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

What is claimed is:

1. A conductive structure comprising:
a conductive pad that includes a first seed layer having a first area and a second area surrounding the first area, and a first metal layer disposed on the first area of the first seed layer; and
a conductive pillar disposed on the conductive pad,
wherein a thickness of the conductive pad in an area vertically overlapping the first area of the first seed layer is thicker than a thickness of the conductive pad in an area vertically overlapping the second area of the first seed layer.

2. The conductive structure of claim 1, wherein the conductive pad further comprises a second metal layer disposed on the first metal layer and containing nickel (Ni).

3. The conductive structure of claim 2, wherein the conductive pad further comprises a third metal layer disposed on the second metal layer and containing gold (Au).

4. The conductive structure of claim 1, wherein a diameter of the conductive pillar is smaller than a diameter of the conductive pad.

5. The conductive structure of claim 1, wherein the conductive pillar comprises a second seed layer and a second metal layer disposed on the second seed layer.

6. The conductive structure of claim 5, wherein a thickness of the second metal layer is thicker than a thickness of the first metal layer.

7. A semiconductor chip comprising:
a body comprising a connection pad; and
a conductive structure disposed on the connection pad,
wherein the conductive structure comprises:
a conductive pad that includes a first seed layer including a first area and a second area surrounding the first area, and a first metal layer disposed on the first area of the first seed layer; and
a conductive pillar disposed on the conductive pad, and
a thickness of the conductive pad in an area vertically overlapping the first area of the first seed layer is thicker than a thickness of the conductive pad in an area vertically overlapping the second area of the first seed layer.

8. The semiconductor chip of claim 7, wherein the conductive pad further comprises a second metal layer disposed on the first metal layer and containing nickel (Ni).

9. The semiconductor chip of claim 8, wherein the conductive pad further comprises a third metal layer disposed on the second metal layer and containing gold (Au).

10. The semiconductor chip of claim 7, wherein a diameter of the conductive pillar is smaller than a diameter of the conductive pad.

11. The semiconductor chip of claim 7, wherein the conductive pillar comprises a second seed layer and a second metal layer disposed on the second seed layer.

12. The semiconductor chip of claim 11, wherein a thickness of the second metal layer is thicker than a thickness of the first metal layer.

13. The semiconductor chip of claim 7, further comprising a protective layer disposed on the body and exposing the connection pad.

14. A manufacturing method of a conductive structure, comprising:
forming a conductive pad; and
forming a conductive pillar on the conductive pad,
wherein the forming of the conductive pad comprises:
forming a first seed layer including a first area and a second area surrounding the first area;
forming a first metal layer on the first area of the first seed layer;
forming a photoresist layer to cover the second area of the first seed layer and the first metal layer;
etching an exposed area of the first seed layer; and
removing the photoresist layer.

15. The manufacturing method of the conductive structure of claim 14, wherein the forming of the conductive pillar comprises:
forming a second seed layer; and
forming a second metal layer on the second seed layer.

16. The manufacturing method of the conductive structure of claim 15, wherein:
in the forming of the second seed layer, the second seed layer is formed on the first metal layer and on the second area of the first seed layer,
in the forming of the second metal layer, the second metal layer is formed on the second seed layer formed on the first metal layer, and
the forming of the conductive pillar further comprises etching the second seed layer formed on the second area of the first seed layer.

17. The manufacturing method of the conductive structure of claim 15, wherein:
the forming of the second metal layer is carried out by electroplating.

18. The manufacturing method of the conductive structure of claim 15, wherein the second metal layer is formed to have a diameter that is smaller than a diameter of the first metal layer.

19. The manufacturing method of the conductive structure of claim 14, wherein the forming of the conductive pad further comprises forming a second metal layer on the first metal layer.

20. The manufacturing method of the conductive structure of claim 19, wherein the forming of the conductive pad further comprises forming a third metal layer on the second metal layer.
